(19) United States
(12) Patent Application Publication
(10) Pub. No.: US 2024/0393215 A1
(43) Pub. Date: Nov. 28, 2024

(54) SYSTEMS, METHODS, AND DEVICES FOR ACHIEVING SUITABLE SAMPLE THICKNESS FOR SINGLE PARTICLE CRYO-ELECTRON MICROSCOPY

(71) Applicant: MiTeGen, LLC, Ithaca, NY (US)

(72) Inventors: Robert E. Thorne, Ithaca, NY (US); An Zou, Dryden, NY (US)

(73) Assignee: MiTeGen, LLC, Ithaca, NY (US)

(21) Appl. No.: 18/707,296

(22) PCT Filed: Dec. 8, 2022
(86) PCT No.: PCT/US2022/081135

§ 371 Date: May 3, 2024

Related U.S. Application Data
(60) Provisional application No. 63/287,727, filed on Dec. 9, 2021.

(51) Int. Cl. G01N 1/42; H01J 37/20

(52) U.S. Cl. CPC G01N 1/42; H01J 37/20

(57) ABSTRACT

Presented are systems, methods, and devices for provisioning sample support, controlled liquid deposition, and/or desired sample thicknesses during cryo-electron microscopy processes. A sample support for a cryo-electron microscopy process includes a support grid with multiple grid faces. The grid may be substantially rigid, flat and circular, may have a diameter of between about 2.9 and 3.1 mm, and may have a thickness of about 10 to 25 μm. A foil covers at least one of the grid faces and includes multiple foil regions that each has a distinct thickness. The foil may be a thin and flexible metal or carbon foil. At least one of the foil regions contains an array of through-holes. A boundary between the foil regions with distinct thicknesses forms a step edge that pins thereto a receding contact line of a liquid drop deposited on the foil.

### CLAIM OF PRIORITY AND CROSS-REFERENCE TO RELATED APPLICATION

This application claims the benefit of and priority to U.S. Provisional Patent Application No. 63/287,727, which was filed on Dec. 9, 2021.

### TECHNICAL FIELD

The present disclosure relates generally to the field of biotechnology. More particularly, aspects of this disclosure relate to the design of sample supports and to methods for depositing and removing liquid from these sample supports for cryo-electron microscopy.

### BACKGROUND

Single-particle cryo-electron microscopy (cryo-EM) is a powerful approach to obtaining near-atomic-resolution structures of large biomolecular complexes, membrane proteins, and other targets of major scientific, pharmaceutical, and biotechnological interest. Development of high-efficiency, high-frame-rate direct electron detectors, algorithms for correcting acquired “movies” for electron-beam-induced motion, and computational tools for classifying and averaging 10⁵-10⁶ molecular images have dramatically increased achievable resolution and throughput. Enormous investments in new cryo-EM facilities and the development of easy-to-use software have greatly expanded access, especially to non-experts. Unlike X-ray crystallography, cryo-EM necessitates only a small amount of biomolecular sample dispersed in solution. It allows structural study of systems that have been intractable to crystallization, and is becoming a go-to method for initial attempts at structure determination.

As in X-ray cryocrystallography, key challenges in single-particle cryo-EM are associated with sample preparation and handling. Many basic principles and methods in current use were developed in the 1980s. Biomolecule samples oftentimes must be expressed, isolated, and purified. Cryoprotectant-free buffers containing a biomolecule of interest may be dispensed onto glow-discharge cleaned and charged foil supported by a metal grid. Excess sample may be removed by blotting and evaporation, with a target thickness of several times the biomolecular diameter to maximize image quality while limiting the fraction of biomolecules preferentially oriented by interaction with interfaces. To vitrify the buffer for best imaging, the sample-containing foil+grid is plunged at 1-2 m/s into liquid ethane at temperatures (T) of about 90 Kelvin (K) (e.g., produced by cooling gas in a liquid-nitrogen-cooled cup). The sample is transferred from ethane to liquid nitrogen (LN₂), loaded into grid boxes, transferred to additional containers and then a storage Dewar. Samples are removed from the storage Dewar and grid boxes, and loaded into a cold microscope stage or else “clipped” and loaded into a cold sample cassette: the stage or cassette is then loaded in the microscope.

These complex procedures are fraught with difficulty. Grids and especially foils are routinely bent, torn, and otherwise damaged at each of the many manual handling steps. Sample dispensing, blotting, and evaporation are oftentimes imprecise. Final sample film thicknesses may be poorly controlled. Biomolecules may accumulate at interfaces where they may have preferential orientation or undergo denaturation. Plunge cooled samples often develop significant crystalline ice, and may be contaminated by ice that forms on ethane, nitrogen, and other cold surfaces exposed to moisture. When first irradiated by the electron beam during imaging, the vitrified samples undergo rapid motion that may blur the images and may cause large loss of information.

A major set of challenges is related to obtaining sample films of suitable thickness for high-contrast particle imaging. Electron scattering by surrounding solvent adds background and reduces particle contrast, so films are ideally comparable in thickness to the particle diameter (e.g., ˜6 nm for MW˜100 kDa, 13 nm for 1 MDa, ˜30 nm for 10 MDa, assuming compact particles). The corresponding sample film volumes, e.g., over the active area of a grid, are between ˜30 and 500 pL. These volumes are ˜10⁻⁴-10⁻⁵ of the 1-3 μL of sample solution initially deposited on the foil+grid, and correspond to the volumes of single ˜40 and 100 μm diameter drops, respectively.

Particles may accumulate at interfaces—the air-solution interface, the solution-support foil interface, and/or the solution-support film interface (if continuous graphene/graphene oxide/amorphous carbon films are used). This may increase (and sometimes decrease) areal particle densities from values expected from bulk solution densities, reducing the number of images that typically need to be acquired to record a desired number (typically ˜10⁵) of particles. However, thicker sample films may have two interface-concentrated particle layers and additional particles dispersed between them. The interfacial density and the proximity of the two interfaces may cause particle image overlap. Useable particle images may then be collected only near the center of foil holes where the sample film may have thinned so as to support only a single particle layer. In addition, particles often exhibit preferential orientation at interfaces and may undergo partial denaturation.

### SUMMARY

There are presently no methods to reliably produce aqueous films with a target thickness in the range of 10-150 nm over a substantial fraction of a grid's area. Dispensing a large sample volume and then blotting nearly all of it away using filter paper is highly imprecise, depending on variables including blot pressure, blot time, temperature, relative humidity, and whether or not the filter paper has equilibrated with that humidity. The resulting film thickness varies from grid to grid and across each grid, e.g., due to the complex and spatially nonuniform interaction of fibrous filter paper with the sample liquid, especially as the filter paper is withdrawn from contact with the sample support foil: due to subsequent surface-tension-driven film relaxation, and due to concurrent evaporation that, in ambient humidities below ˜95% relative humidity (r.h.), can reduce film thickness by a substantial fraction of the target value in seconds. Other sample deposition approaches have been demonstrated and a few have been commercialized but it is not clear that any give substantially better performance in real-world application.

Most of a typical grid's accessible area may be unusable for imaging, e.g., because there is no solution present, because the solution film is too thick, because of the presence of crystalline ice, and/or because the foil and sample are damaged. As such, many grids may need to be prepared and screened for each one that eventually yields usable single-particle image data, and the amount of such data per imaged grid may be small. Given the costs of grids and of staff time to prepare them, the hourly rates for access to state-of-the-art cryo-TEMs, and the very high demand for this access, the impact of these challenges on the overall cost and throughput of cryo-EM structure determination efforts are large.

Aspects of the present disclosure relate to the design, function, and use of sample supports and to methods for depositing and removing liquid from these supports in cryo-electron microscopy. For instance, the disclosure provides an approach to depositing controlled amounts of liquid over a predefined (large) area of a grid and of achieving, e.g., via evaporation and/or blotting, uniform films of a desired thickness in imaging-accessible parts of the support foil.

In at least some applications, cryoprotectant-free buffers containing, for example, ˜0.3 mg/mL of a biomolecule of interest may be dispensed onto a glow-discharge cleaned and charged, ˜10-50 nm thick carbon or metal (often gold) “foil” supported by a ˜200-400 mesh, ˜10-25 μm thick, ˜3 mm diameter metal (e.g., copper or gold) grid. Excess sample may be removed by blotting and/or evaporation, with a target thickness of several times the biomolecular diameter (e.g., ˜10-50 nm) to maximize image quality while limiting the fraction of biomolecules oriented by interaction with interfaces.

Aspects of this disclosure are directed to innovations to grids and foils that provide greater control over sample film thicknesses.

According to at least one embodiment, the foil on the grid has regions of at least two different thicknesses, where each region may have an array of closely-spaced through-holes.

According to at least one embodiment, a thickness of each foil region may be comparable to a predefined target sample film thicknesses, e.g., in a range of about 5 to 150 nm.

According to at least one embodiment, a boundary between adjacent thinner and thicker regions of the sample support foil may define a step edge.

According to at least one embodiment, a step edge may include an inclined surface having an oblique angle of inclination that is greater than about 30 degrees and, for at least some implementations, greater than about 60 degrees relative to a horizontal, transverse plane of the foil.

According to at least one embodiment, a step edge is structurally configured to pin advancing or receding contact lines formed by liquid drops deposited on the foil surface.

According to at least one embodiment, the pinning of the receding contact line of liquid residing on a thinner region by the step edge at a boundary with a thicker region allows liquid to be removed from the thinner region by blotting, evaporation or other techniques without surface-tension driven contraction of the film within the thinner region, allowing formation of thinner and nearly uniform thickness liquid films in the thinner region and in the through-holes within that region.

According to at least one embodiment, a step edge may form a continuous rim, e.g., with a circular shape, an oval shape, a square shape, or other closed shape (e.g., in a plan-view profile). If desired, a step edge may form an open shape, such as parallel or diverging/converging lines in the plane of the foil.

According to at least one embodiment, a smallest lateral dimension of a thinner foil region may be between about 20 to 500 μm.

According to at least one embodiment, a thicker foil region may form narrow annular rings with a width of the thick region between about 5 and 100 μm. An outer edge of these rings may be structurally configured to pin the advancing liquid contact line of a drop deposited on the foil and keep it from spreading to the region beyond.

Aspects of this disclosure are also directed to systems, methods, and devices for producing sample support foils with regions of different thickness.

In at least one approach, a film of one thickness is deposited onto a master that defines a pattern of through-holes in the foil. A shadow mask formed of a metal, polymer, or glass sheet is then placed immediately above the foil, e.g., in close (within about 5 μm) but not necessarily direct contact with the foil, and a second layer of film is deposited. This process can be repeated by rotating and/or displacing the same mask to produce films with multiple thicknesses, or by using successive masks with different patterns.

In at least one embodiment, the foil can be fabricated using thin film processes involving photolithography, metal deposition, and photoresist removal for each foil layer.

Aspects of this disclosure are also directed to systems, devices, and methods for controlled deposition onto and removal of biomolecule-containing liquid from a surface of a foil+grid sample support assembly.

In at least one embodiment, biomolecule-containing liquid is deposited on an array of pillars. Liquid is then withdrawn, e.g., by blotting or suction or removed by vibration, leaving liquid on top of the pillars. The volume of liquid on each pillar may be determined by a pillar diameter and the liquid's contact angle on the top of the pillar. The pillar array is pressed into near contact or contact with a foil+grid sample support and withdrawn, e.g., so that liquid is transferred from the pillar array to the foil. The volume of liquid transferred may be determined, for example, by the pillar diameter, a pillar areal density, and a liquid contact angle on the top of the pillar.

In at least one embodiment, the pillar top is hydrophilic, e.g., for use with liquids that do not contain detergents or lipids in large concentrations.

In at least one embodiment, the pillar top is hydrophobic, e.g., with a contact angle for water between about 0° and about 30°.

In at least one embodiment, the pillar diameters are between about 5 and about 50 μm, and hold between about 2 fL and about 10 pL per pillar.

In at least one embodiment, a pillar-to-pillar separation between neighboring pillars may be set so that liquid transferred per unit area of foil corresponds to an average liquid thickness between about 10 and 150 nanometers, and to an average liquid volume per unit area between about 10 and 150 pL/mm².

In at least one embodiment, a cumulative area of the pillar array may be comparable to a central, electron-microscope-imaging-accessible area of the grid, e.g., roughly about 2 to 2.5 mm in diameter.

In at least one embodiment, the pillar array may contain pillars of different diameters in different regions that will deposit different amounts of liquid per unit area on a foil and, thus, produce liquid films of different average thickness on different regions of the foil.

In at least one embodiment, the pillar array may have channels running parallel to the axes of the pillars that connect, e.g., via through-holes, to a cavity beneath the pillar array, through which liquid can be injected onto the pillar array and through which liquid can be withdrawn, leaving only liquid on the pillar tops and no liquid between the pillar tops.

In at least one embodiment, select portions of the pillars and channels include or are made, in whole or in part, from a hydrophobic material.

In at least one embodiment, a top and substantially flat surface of the pillars include or are capped by a hydrophilic layer.

In at least one embodiment, liquid is injected onto the pillars through a tube connected to a cavity on a backside of the pillar array, e.g., using a syringe and/or a pump.

In at least one embodiment, the pillar array and tube are mounted on a precision linear motion stage that drives the pillar array into near contact or contact with the foil-covered grid.

In at least one embodiment, the linear motion is driven by piezoelectric elements.

In at least one embodiment, the pillar array is fabricated by molding PDMS using a microfabricated silicon mold, and then depositing a hydrophilic metal, such as Au or Cu, on top of the pillars.

In at least one embodiment, the pillar array and tube are operatively attached to an electronic vibration device or means for vibrating the tube and pillar array. The device/means may include a solenoid, a magnet and coil, a piezoelectric device such as a tube scanner, and/or a linear translation stage.

In at least one embodiment, the pillar array is vibrated in a plane perpendicular to the plane of the pillar array.

The above Summary does not represent every embodiment or every aspect of the present disclosure. Rather, the foregoing synopsis merely provides an exemplification of some of the novel concepts set forth herein. The above features and advantages, and other features and attendant advantages of this disclosure, will be readily apparent from the following detailed description, illustrated examples, and representative modes for carrying out the disclosure when taken in connection with the accompanying drawings and the appended claims. Moreover, this disclosure expressly includes any and all combinations and subcombinations of the elements and features presented above and below.

### BRIEF DESCRIPTION OF THE DRAWINGS

FIG. 1(A) illustrates an example of a cryoEM grid covered with a holey foil.

FIG. 1(B) is an enlarged, sectional illustration showing protein particles embedded in ice spanning holes in the example of commercially available foil of FIG. 1(A).

FIGS. 2(A)-2(C) illustrate an example of an available method for preparing cryo-EM samples.

FIGS. 3(A)-3(C) illustrate a liquid drop on an otherwise flat and inclined surface that has a raised ring with a nearly trapezoidal cross-section in accord with aspects of the disclosed concepts.

FIGS. 4(A)-4(C) illustrate an example effect of a 500 nm high ring on a liquid drop deposited within it on an otherwise flat surface.

FIGS. 5(A)-5(C) illustrate an example of a grid covered with a foil that has regions of different thicknesses as well as through holes in accord with aspects of the disclosed concepts.

FIG. 6 illustrates an example of motion of an air-liquid interface and a contact line (air-liquid-solid) as a drop of liquid is blotted or evaporates on a foil with a surface step and a through-hole in accord with aspects of the disclosed concepts.

FIGS. 7(A)-7(C) illustrate an example of how a raised ring—a step up and down in foil thickness—may be used to pin an advancing contact line of a liquid drop and prevent the liquid from spreading to outer regions of the foil, e.g., including those gripped by forceps during liquid deposition in accord with aspects of the disclosed concepts.

FIGS. 8(A)-8(D) illustrate an example of a process using a single shadow mask for depositing a foil with regions of multiple different thicknesses and through-holes in accord with aspects of the disclosed concepts.

FIGS. 9(A)-9(B) illustrate an example of a shadow mask for making a large area foil that has regions of different thickness and is suitable for covering multiple grids in accord with aspects of the disclosed concepts.

FIGS. 10(A)-10(C) illustrate an example of an apparatus and method for depositing a precisely controlled volume of drops over a predefined (large) area of foil on a grid in accord with aspects of the disclosed concepts.

FIGS. 11(A)-11(B) illustrate an example of top and bottom views of a deposition head including a pillar array with through channels and a backside cavity, where different regions of the array have pillars of different diameters in accord with aspects of the disclosed concepts.

FIGS. 12(A)-12(C) illustrate examples where excess liquid may be removed from the pillar array by vibration, and where liquid deposition is performed on a moving grid in accord with aspects of the disclosed concepts.

FIGS. 13(A)-13(C) illustrate an example of a process for fabricating deposition heads for the apparatus shown in FIG. 11.

The present disclosure is amenable to various modifications and alternative forms, and some representative embodiments are shown by way of example in the drawings and will be described in detail herein. It should be understood, however, that the novel aspects of this disclosure are not limited to the particular forms illustrated in the above-enumerated drawings. Rather, the disclosure is to cover all modifications, equivalents, combinations, subcombinations, permutations, groupings, and alternatives falling within the scope of this disclosure as encompassed by the appended claims.

### DETAILED DESCRIPTION

This disclosure is susceptible of embodiment in many different forms. Representative examples of the disclosure are shown in the drawings and will be described in detail herein with the understanding that these representative examples are provided as an exemplification of the disclosed principles, not limitations of the broad aspects of the disclosure. To that extent, elements and limitations that are described in the Abstract, Technical Field, Background, Summary, and Detailed Description sections, but not explicitly set forth in the claims, should not be incorporated into the claims, singly or collectively, by implication, inference or otherwise.

For purposes of the present detailed description, unless specifically disclaimed: the singular includes the plural and vice versa: the words “and” and “or” shall be both conjunctive and disjunctive: the words “any” and “all” shall both mean “any and all”; and the words “including”, “comprising”, “having”, “containing”, and the like shall each mean “including without limitation.” Moreover, words of approximation, such as “about,” “almost”, “generally”, “substantially”, “approximately”, and the like, may be used herein in the sense of “at, near, or nearly at,” or “within 0-5% of,” or “within acceptable manufacturing tolerances”, or any logical combination thereof, for example. Lastly, directional adjectives and adverbs, such as top, bottom, upper, lower, vertical, horizontal, front, back, left, right, etc., may be with respect to a cryo-EM system or device when operatively oriented on a flat and horizontal worksurface, for example.

Aspects of this disclosure are directed to producing liquid films of controlled thickness between 10 and 150 nm over a substantial fraction of the area of a standard 3 mm diameter foil+grid used in cryo-EM by combining innovations in foil design with innovations in liquid deposition technology.

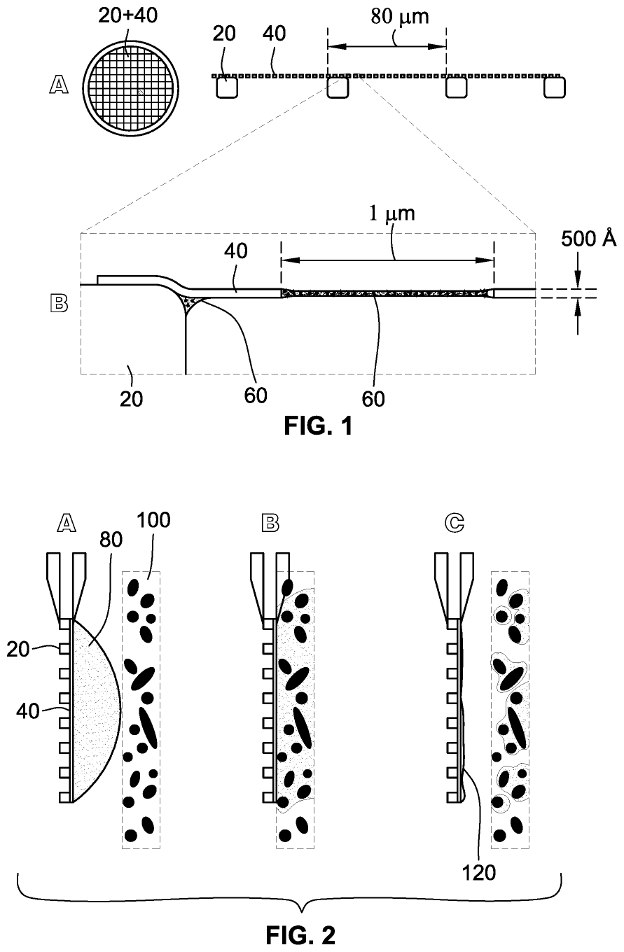

FIG. 1 shows an example of a cryo-EM grid 20 covered by a thin foil 40 (in this case, of gold), with liquid 60 containing biomolecules spanning holes in the foil. The situation shown represents a highly favorable situation for cryo-EM data collection, where the liquid film spanning the hole has a single layer of biomolecules, that is difficult to achieve in practice. The foil may be of a wide variety of metals and metal alloys (e.g., Au, Cu, Ni, W, Ti, Mo), or of various forms of carbon.

FIG. 2 shows a standard method to prepare samples for single-particle cryo-EM. Typically, 1-3 μL of biomolecule containing solution 80 is deposited on a grid 20 covered by foil 40, which is held by forceps 90. The foil is blotted using fibrous filter paper 100, which draws liquid away from the foil surface in a spatially non-uniform way. Liquid bridges between the filter paper and foil break as the filter paper is withdrawn, and the remaining liquid on the foil relaxes due to surface tension forces. Within the foil holes where imaging will occur, attractive forces between the two liquid-air interfaces drive thinning and possible breakage of the sample film. Evaporation occurs rapidly once the filter paper is withdrawn, driving further film thinning, breakage, and contact line motion. With luck, the final liquid film 120 may have a few small areas where the foil holes are spanned by films with suitable thickness and suitable particle densities for high contrast imaging (FIG. 1).

There are currently no methods to reliably produce aqueous films with a target thickness in the 10-150 nm (and more typically between 10 and 100 nm) range over a substantial fraction of a grid's area. Dispensing a large sample volume and then blotting nearly all of it away using filter paper is highly imprecise, depending on variables including blot pressure, blot time, temperature, relative humidity, and whether or not the filter paper has equilibrated with that humidity. The resulting film thickness varies from grid to grid and across each grid, due to the complex and spatially nonuniform interaction of fibrous filter paper with the sample liquid, especially as the filter paper is withdrawn from contact with the sample support foil: due to subsequent surface-tension-driven film relaxation; and due to concurrent evaporation that, in ambient humidities below ˜95% relative humidity (r.h.), can reduce film thickness by a substantial fraction of the target value in seconds.

At least three issues associated with current grids and foils limit the ability to achieve sample films of optimal thickness, in the 10-150 nm range, and over a large area of the grid. First, advancing and receding contact angles for water drops on clean sample support foils (and on graphene, graphene oxide, and related continuous mono and bilayer films used to address interface issues) are all substantial—in the range of 60°-100°. Cryo-EM solution components including protein and surfactants can reduce contact angles, but the smallest angles observed are still 10-15°. Even with a 15° contact angle, a ˜40 nm high drop will have a width of only 0.6 μm-smaller even than the holes in most foils—and a volume of <0.01 fL.

Second, if solution is blotted from the flat foil surface, the thickness of remaining solution in the foil's holes is limited by the foil thickness. Au foils are typically 40 nm thick, as thinner foils are too fragile and too hard to assemble onto grids without damage. 40 nm is thicker than an optimal film thickness for at least some targets of interest, and thinner than that needed for at least some very large complexes.

Since biomolecules tend to accumulate at the air-solution interface, optimal imaging conditions are often obtained when the sample film is too thin to support two separate interfacial accumulation layers, or roughly within a factor of two or three of the biomolecule size. Based on typical molecular sizes of less than 10 nm, this suggests that foils significantly thinner than the 40 nm of typical gold foils would be helpful. Holey and amorphous carbon foils are typically 10-15 nm thick but are believed to produce more severe beam-induced motion and yield inferior single-particle image quality.

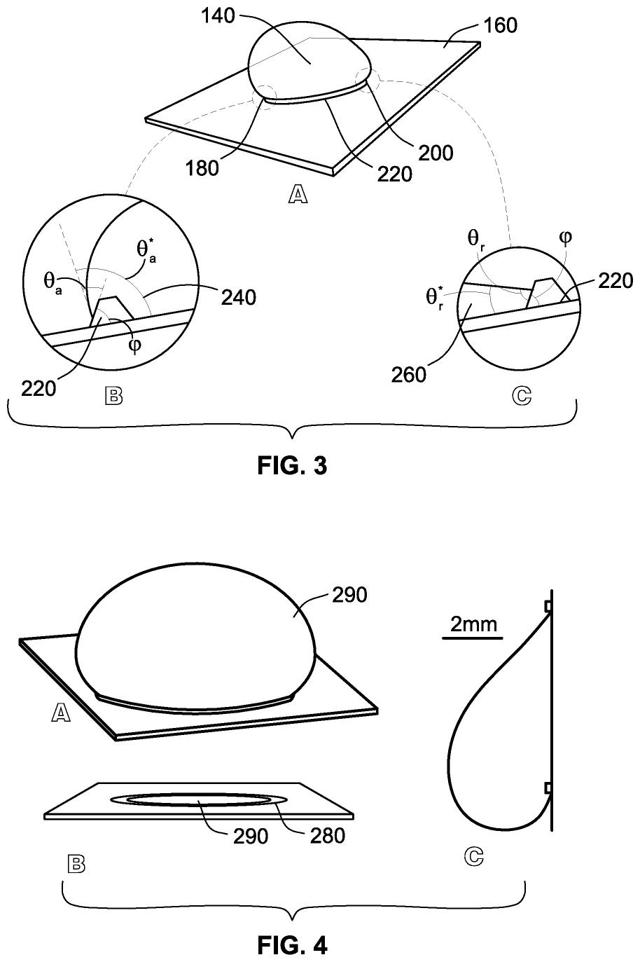

Optimizing foils to achieve greater control over liquid film thicknesses and uniformity. The present disclosure is inspired by past studies of pinning of liquid contact lines on surfaces. As shown in FIG. 3(A), for a drop 140 on a flat inclined surface 160, as the angle of inclination increases, the contact angle at the downhill (advancing) edge of the drop 180 increases to a maximum value θₐ before the contact line depins from the surface and moves downhill. Similarly, the contact angle at the uphill (receding) edge of the drop 200 decreases to a minimum value Or before the contact line depins from the surface and moves downhill. For a drop on a horizontal surface, as additional liquid is added to the drop, the contact line will remain pinned until a needed contact angle to hold the drop volume exceeds θₐ; as liquid is withdrawn from the drop, the contact line will remain pinned until a needed contact angle to hold the drop volume drops below θᵣ.

By adding steps in thickness or rings 220 with near vertical sidewalls, the maximum advancing angle can be greatly increased, and the minimum receding contact angle can be greatly decreased (FIG. 3). If the sidewall angle/angle of inclination is φ, the drop's maximum advancing contact angle 240 increases from that on a flat surface to θₐ⁺=θₐ+φ(FIG. 3B) and the drop's minimum receding contact angle 260 decreases to θᵣ*=θᵣ−φ or 0°, whichever is larger (FIG. 3C).

As shown in FIG. 4, the increased advancing angle (from the “flat”) θₐ˜50° caused by a 500 nm high ring polymer ring 280 allows “overfilling” of a water drop 290 (FIG. 4(A)) on an otherwise flat horizontal silicon surface, and the decreased receding angle (from θᵣ˜20° to) 0° caused by the ring allows liquid to be withdrawn from the drop to produce a thin film of the same diameter as the original drop (FIG. 4(B)), a far larger diameter than could be sustained under the influence of surface tension without the ring and its steps in thickness. The ring also allows a far larger volume of liquid to remain pinned to a given area when the surface is rotated to the vertical. Thus, steps in thickness provide a way to reduce the receding contact angle of a drop that is being blotted or is evaporating to 0° and to prevent contraction of its area, facilitating formation of much thinner liquid films.

The present disclosure presents foils for cryoEM grids that have steps in thickness to pin receding or advancing contact lines of liquid deposited upon them. These steps can prevent spreading of the deposited liquid to areas of the foil that should be kept dry (e.g., near foil edges where they will be gripped with forceps or related tools, and where frozen liquid between the forceps and foil could inhibit release of the grid from the forceps after cooling). These steps can strongly pin receding contact lines as a liquid is blotted or evaporates, allowing much thinner liquid films than is possible when the remaining liquid is allowed to contract under surface tension forces. Furthermore, foil thickness is, together with foil hole size, the most critical geometric parameter of grid+foil in determining final sample film thickness and thus whether single particle imaging is feasible. Ideally, blotting and evaporation remove nearly all liquid except that within the holes, so that the foil thickness determines the liquid film thickness. Having regions of the foil with different thicknesses thus facilitates creating liquid films within the holes in the foil having different thicknesses.

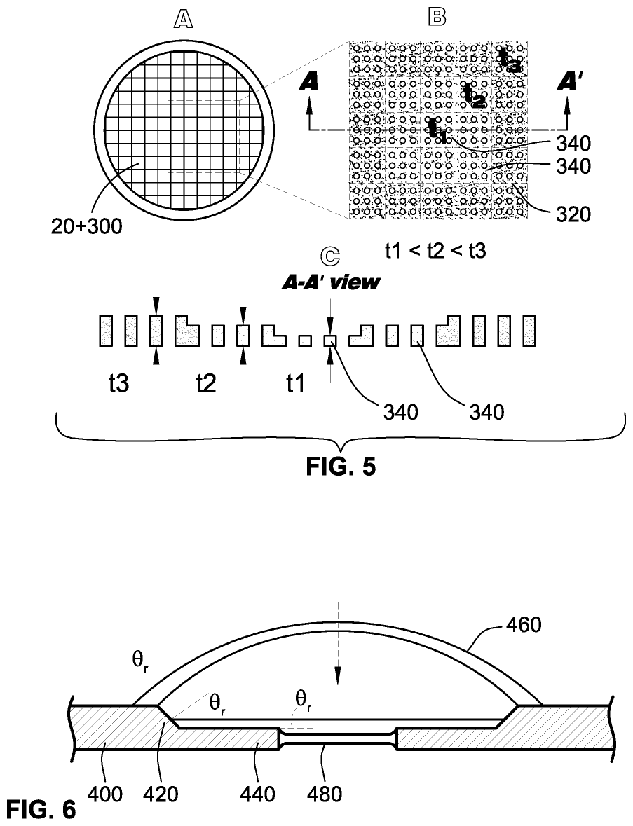

In an embodiment shown in FIG. 5, a foil 300 may have a thick outer region 320—possibly thicker than the current 40 nm (and possibly a thick internal meshwork) to ensure that the foil is robust and easy to handle. Interior regions 340 can have reduced thickness-down to 10 nm or 5 nm. As long as the thinnest regions each have a small area, they should not compromise foil robustness. Thick and thin regions will then promote formation of films within their holes with corresponding thicknesses, suitable for imaging of larger and smaller particles, respectively.

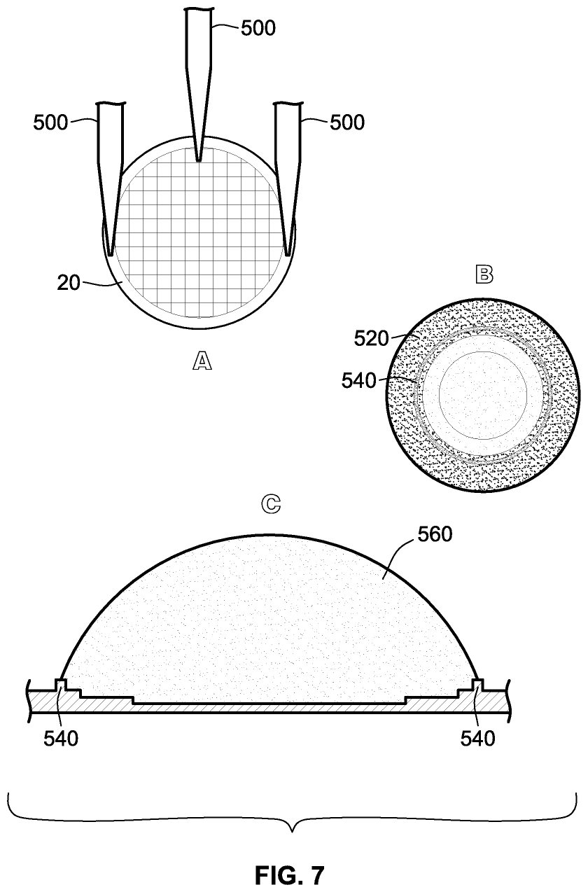

FIG. 6 shows how a foil 400 with a step in thickness 420 surrounding a thinner foil region 440 will affect liquid contact line motion and distribution as liquid 460 is removed by evaporation or blotting from the foil. The thickness step height has a practically useful range between 10 and 150 nm, set by the maximum foil thickness and hole depth that can give good cryoEM imaging. However, if the step is part of an isolated ring that separates different foil regions (FIG. 7), it can be up 1 μm tall. The angle of the step depends on the foil fabrication method but should be at least 30° or, in some applications, at least 45° or greater and, if desired, 70° or greater, to ensure that the receding contact angle is close to 0°. On the flat foil surface, the minimum receding contact angle θᵣ (determined by the liquid-metal surface interaction) dictates the drop shape for a given volume. But once the drop's contact line has contracted-via blotting or evaporation—to the step edge, the effective receding contact angle decreases to near zero (if the step inclination angle is greater than Or) and the liquid surface flattens. Oftentimes, a substantial amount of additional liquid must be removed before the contact line depins from the step edge and the drop contact line reaches the flat foil surface and contracts toward the hole 480. A similar sequence occurs once the contact line reaches the walls of the hole.

FIG. 7 (A) shows a grid 20 held by forceps 500 either at its top or along its edges, as occurs during grid handling and plunge cooling. FIG. 7 (B) shows how a foil 520 with a thicker ring 540 (with width of 5-100 μm) can prevent spreading of liquid during deposition to foil regions that are to be kept dry. The outer step of the ring can pin the advancing contact line of liquid 560 as it is dispensed on the foil (FIG. 7 (C)) and prevent liquid from moving beyond the ring and wetting the forceps. Similarly, when the liquid is blotted or evaporates, the inner step of the ring will pin the receding contact line. Foils are typically generated by depositing a soluble release layer on a master and evaporating Au, Cu, or other metal or metal alloy or C. The foils are then floated off the master in water. The foils have features (holes) as small as ˜0.2 μm, and the master may be generated using e-beam or UV lithography. The master can be cleaned and reused to fabricate many foils, which is essential to achieving acceptable production costs with sub-micron feature sizes.

Multilayer foils with similar feature sizes could be fabricated using electron-beam or UV lithography and a multistep expose/develop/bake/deposit/strip process, but the cost per foil would be commercially unacceptable.

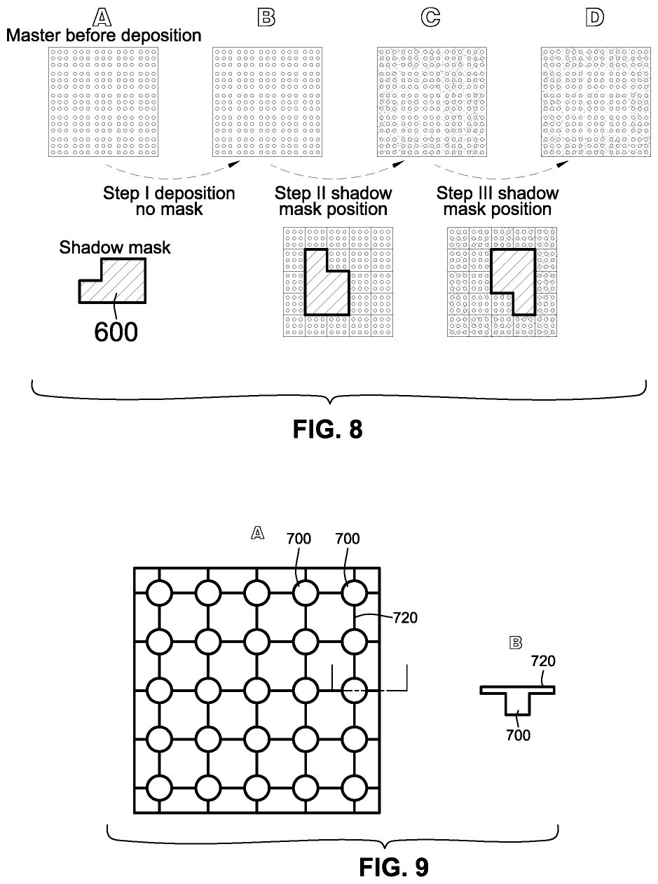

The simplest approach to produce foils of two or more thicknesses is to evaporate a uniform base foil layer onto a master that defines the hole pattern. A shadow mask can be rotated or translated into place, in near contact with the master, and an additional thickness evaporated onto areas not blocked by the mask. A foil with thickness that steps up at increasing radii could be fabricated by using disk-shaped shadow masks of increasing radius during successive depositions of metal or carbon. The innermost foil region would then be thinnest, and the outer periphery thickest. FIG. 8 illustrates a process using a single solid shadow mask 600 in which the mask is rotated 180° after a first masked deposition to produce concentric foil regions having three thicknesses (or four, if the evaporations each deposit different metal thicknesses). A similar mask with rounded edges can be used to fabricate circular instead of square regions of different thickness.

The shadow masks could be fabricated using standard photolithographic and etching processes from, e.g., 1 mil/25 μm thick Cu foil or from a photo-exposable polymer like SU-8 or polyimide. In order to repeat the shadow pattern over a large area of foil suitable for covering many grids, the solid/shadowing features 700 of the shadow mask should be connected by thin lines or struts 720 (FIG. 9A). To ensure that the foil thickness is not excessively reduced beneath these struts (which could become creases for bending or provide defects in steps and rings that promote contact line motion), a two-layer shadow mask can be fabricated with the struts located in the upper layer, away from the master's surface (FIG. 9 B). For example, using sheet material of photoexposable SU-8, the bottom layer with only the disks could be 0.2 to 1 mm (or more) thick while the top layer could be perhaps 50-200 μm thick with struts 25-100 μm wide. Multi-angle evaporation or fixed angle evaporation with the substrate rotated, e.g, 90° between evaporations can then be used to “fill in” the struts. A precision shadow mask holder/translation system can be designed and incorporated into the evaporator to allow alignment of shadow mask features to within ˜10 μm, comparable to the smallest drops that can currently be dispensed. The proximity of the mask to the master and foil and mask alignment between any mask rotations will be the most critical parameters affecting the angle of steps.

Apparatus for sample deposition and blotting. Aside from modifying foils and grids to obtain greater control over liquid dynamics on their surfaces, another route to improving the properties of cryo-EM films is to improve sample deposition and removal. Several alternative approaches to the dominant dispense-a-drop and blot approach, particularly for time-resolved cryo-EM, have been demonstrated. For instance, droplet streams generated using piezo dispensing tips or ink-jet technology can be directed at grids as they plunge to the ethane surface. The smallest drops generated this way-having volumes of ˜50 μL and diameters of ˜8 μm-generate micrometer thick films. These can be thinned using “self-wicking”grids whose grid holes are lined with nanofibers. This approach has not appreciably improved control over final film thickness, tends to produce thicker films than can be achieved by hand dispensing and blotting, populates only a small area of each grid with sample, and the wicked liquid increases thermal mass and slows cooling.

Liquid can be deposited on a grid and removed by backside blotting with glass fiber filter paper. Aerosol-type sprays can be generated ultrasonically, using Rayleigh jets, using gas-dynamic virtual nozzles, and using electrospray, but drop sizes are again found to be in the 5-40 μm range, drops are randomly distributed and may overlap on the grid, and, in the absence of blotting/wicking, typically only yield usable film thicknesses at the very edges of drops. These approaches minimize the time between deposition and cooling, which minimizes evaporation, surface-tension driven relaxation, and possibly also particle denaturation at interfaces. Other approaches involve “writing” liquid onto the grid surface using a metal tip that has been dipped in solution, analogous to dip-pen lithography, or using a microcapillary. This approach is slow and technically complex (e.g., the tip or capillary oftentimes must be scanned across the grid surface), deposited thicknesses depend on solution composition and grid surface properties, and there is so far no evidence that it yields improved results.

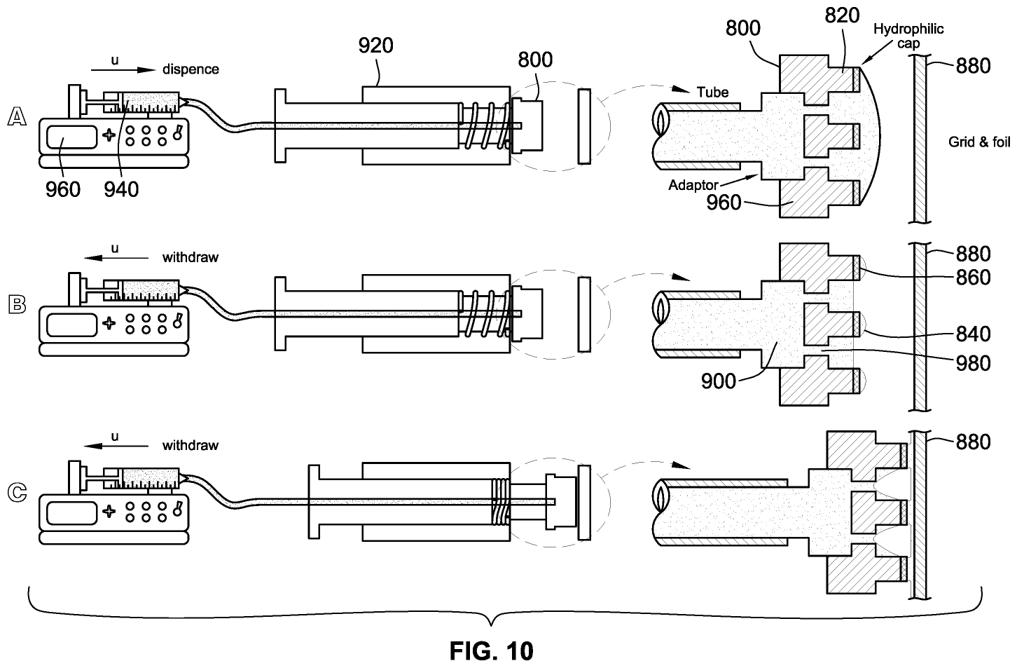

FIG. 10 shows an alternative approach based on the present disclosure that can address issues with presently available deposition systems. The basic concept is to place liquid on top of a deposition head 800 comprised of an array of small cylindrical (or other shaped) pillars 820 (FIG. 10 (A)), remove excess liquid from the pillar array (FIG. 10 (B)), leaving liquid drops 840 on the tops 860 of the pillars and then to bring the pillar array into contact or near contact with a foil+grid 880 to transfer the liquid (FIG. 10 (C)). The pillar top can be hydrophilic while the pillar sidewalls are hydrophobic.

Deposition using pillar arrays is similar to woodcut and to dot density/half-tone printing. For an individual pillar, the maximum liquid volume that can be supported on its top depends on the pillar diameter and the liquid's contact angle, according to the formula for a spherical cap. The fraction of this liquid volume that is transferred to a foil depends on the relative contact angles (hydrophilicity/hydrophobicity) of the foil and pillar, on the area of liquid contact formed during the pillar's closest approach to the foil (which could include full contact), and on the speed with which the pillar is withdrawn. Using an array of such pillars, sample liquid can be uniformly dispensed over the entire active grid area, and the average liquid thickness over that area can be controlled by varying pillar size and separation.

For example, assuming the pillars are capped 860 by Au with a receding contact angle of 15°, a pillar diameter of 10 μm, and that 80% of the liquid on the pillar is transferred to the foil, each pillar will deposit ˜20 fL. To deposit liquid to an average thickness of 40 nm over the active area of the grid may then necessitate a center-to-center pillar separation of ˜20 μm. The contact angle for a given cap material can modified by plasma and other treatments. For example, the contact angle of Au can be reduced to <10° using oxygen plasma treatment. Ar plasma treatment produces larger contact angles. The table below gives calculated liquid transferred to the foil per pillar and pillar separation to achieve average liquid thicknesses on the foil between 10 and 100 nm, for different pillar diameters and cap contact angles, assuming that half the liquid on each pillar transfers to the foil. The bolded values indicate pillar separations that are small enough (within a factor of 2 of the diameter) to give reasonably uniform film thickness after the pillars are pressed into contact with the foil, but that leave enough space (at least 1 μm) between pillars for liquid removal and to ensure that the liquid on each pillar is isolated from its neighbors.

| | Liquid volume | | | |
|---|---|---|---|---|
| Pillar | transferred | Pillar separation for average thickness of | | |
| diameter | per pillar | 10 nm | 30 nm | 100 nm |
| μm | fL (=μm³) | μm | μm | μm |

Pillar contact angle = 10°

| | | | | |
|---|---|---|---|---|
| 3.0 | 0.2 | 4.8 | 2.8 | [symbol] |
| 5.0 | 1.1 | 10.4 | 6.0 | [symbol] |
| 10.0 | 8.6 | 29.3 | 16.9 | [symbol] |
| 15.0 | 29.1 | 53.9 | 31.1 | 17.1 |
| 20.0 | 68.9 | 83.0 | 47.9 | 26.2 |
| 30.0 | 232.0 | 152.3 | 87.9 | 48.2 |
| 50.0 | 1076.0 | 328.0 | 189.4 | 103.7 |

Pillar contact angle = 30°

| | | | | |
|---|---|---|---|---|
| 3.0 | 0.7 | 8.5 | 4.9 | [symbol] |
| 5.0 | 3.4 | 18.4 | 10.6 | [symbol] |
| 10.0 | 26.9 | 51.9 | 29.9 | 16.4 |
| 15.0 | 90.9 | 95.3 | 55.0 | 30.1 |
| 20.0 | 215.0 | 146.6 | 84.7 | 46.4 |
| 30.0 | 727.0 | 269.6 | 155.7 | 85.3 |
| 50.0 | 3367.0 | 580.3 | 335.0 | 183.5 |

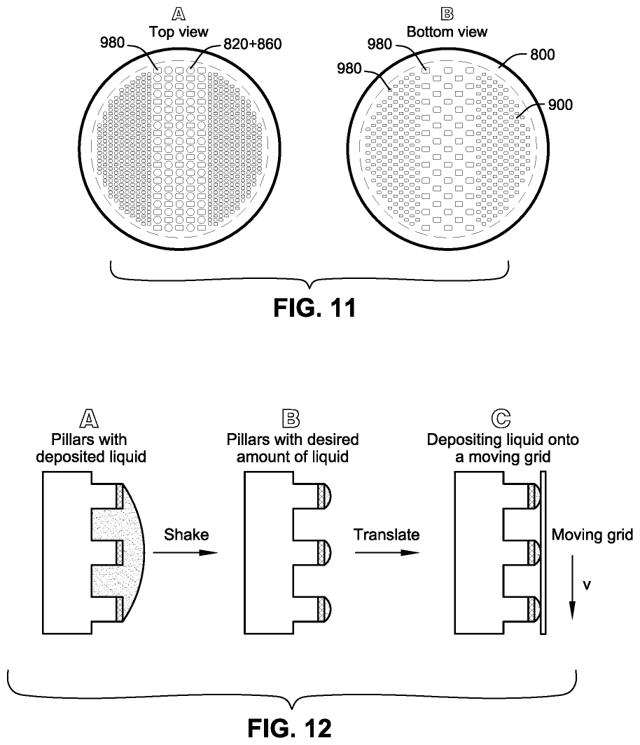

To account for variability/uncertainty in the contact angle and transferred liquid fraction for a given sample solution, the pillar density and diameter can be varied over the active area of the grid (typically about 2-2.5 mm in diameter) (FIG. 11), increasing the chance that there will be some region with an optimal thickness liquid film. Using 5-50 μm diameter pillars with hydrophilic caps, dispensed volumes per pillar can be much smaller-between a few fL and a few pL (and much more reproducible) than those feasible per drop using any of the presently available drop dispensing methods. Using pillar arrays can thus produce films of the appropriate thickness without blotting or evaporation.

FIG. 10 shows how this approach can be implemented in practice. The deposition head 800 is connected via an adapter that inserts into the head's backside cavity 900 to a tube, which is held by an assembly on a linear positioning system 920. This system should allow precise linear motion with step sizes smaller than the pillar radius, or in the micrometer range, so that the deposition head can be brought into near and full contact with the grid. Piezo-electric based linear motion systems have the needed specifications. The deposition head is fed with sample solution by, e.g., a 10 μL Nanofil syringe 940 mounted in a precision syringe pump 960. The positioning system “homes” the deposition head into contact with the grid, and then backs off. Sufficient liquid is injected through channels 980 in the deposition head to “flood” the pillars (FIG. 10 (A)), and then liquid is withdrawn through the channels, leaving isolated drops 840 on the hydrophilic tops of pillars (FIG. 10 (B)). The deposition head is translated into near contact (or full contact) with the grid and withdrawn, uniformly depositing liquid (either as a continuous film or as drops/disks) over the surface of the grid (FIG. 10 (C)). By using a foil with stepped thickness as discussed above, liquid contact lines formed during maximum contact can be pinned, preventing surface-tension driven contraction and film thickening. By using a smooth, slow approach of the head to the grid, pressure spikes that might drive liquid through the foil holes to the backside of the grid can be avoided.

In order for this approach to work reliably, the dispensing/blotting head may be somewhat compliant, the pillars should be capped by an inert and easily cleaned material, the grid, foil, and dispensing/blotting head should all be as flat and parallel as possible, and the grid should be rigidly held.

FIG. 12 shows an alternative approach, where liquid can be deposited using, e.g., a pipette or syringe onto the pillar array (FIG. 12 (A)). The pillar array can then be vibrated/shaken (using, e.g., a mechanical, ultrasonic, solenoid-type shaker) so that the excess liquid is removed, leaving liquid only on the caps of the pillars (FIG. 12 (B)). Transfer of liquid from the pillar heads to a foil+grid can be performed while the grid and deposition head are stationary, and when the foil+grid are being plunged (FIG. 12 (C)) (which necessitates that the deposition head not interfere with grid gripping mechanism.)

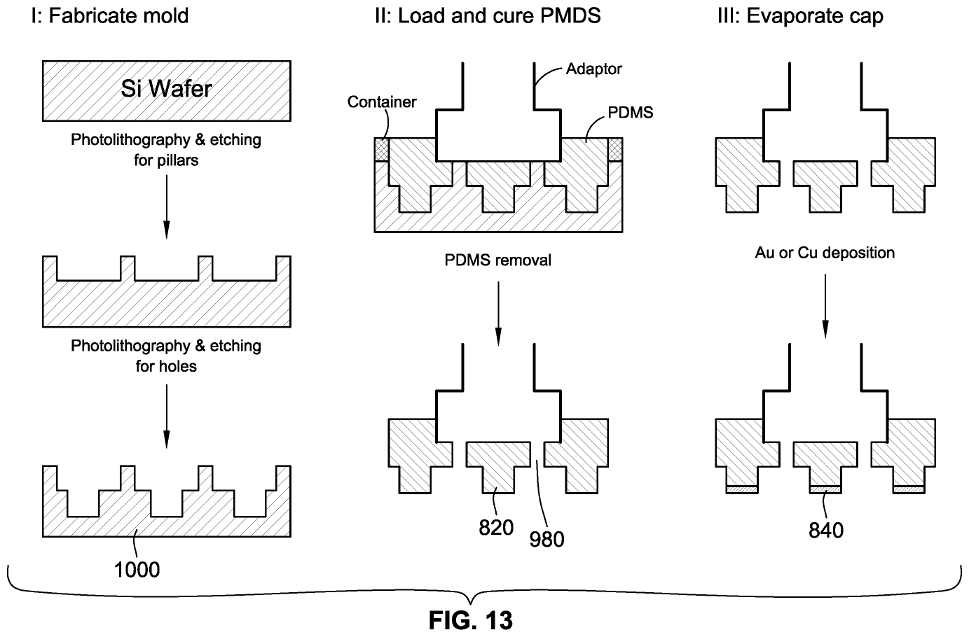

FIG. 13 shows one possible approach for fabricating the deposition heads, using a microfabricated Si mold 1000 to cast PDMS and then depositing a very thin Au or Cu layer on the tops of the pillars. PDMS is naturally hydrophobic, and Au and Cu are both hydrophilic.

The forceps in commercial deposition/blotting/plunge cooler systems hold grids on their upper (upstream) edge, so that the grid has maximum bending moment about the gripping position. This grid gripping approach will not provide adequate grid support for this application. We have designed and prototyped a tool that reliably and rigidly grips grids on two side edges, to ensure absolutely vertical orientation of the grid during plunge cooling. Clipped grids held by keyed forceps in a vertical orientation should also work well. Foils on commercial grids exhibit micrometer-size depressions within each grid opening due to the “mushroom” profile of standard grids and due to capillary forces generated when the foil+grid is dried after assembly. To maximize uniformity of contact of the dispensing head with the foil, we can minimize these depressions by using vertical profile grids and by modifying the foil drying process.

Total sample consumption in our approach can be minimized by incorporating the syringe pump into the deposition head translation stage, and by attaching the deposition head using a suitable adapter directly to the end of the loaded deposition syringe. With the approach in FIG. 13, deposition heads should be very inexpensive to fabricate and so can be exchanged and cleaned each time the syringe is filled with a new solution. With automated control, deposition times should be of order 1 s, minimizing time for evaporation prior to plunge cooling.

The combination of the deposition approach illustrated in FIG. 10 and the multiple-thickness foils with contact line pinning steps illustrated in FIGS. 5-9 address key issues in sample deposition in a reasonably robust and sample independent way. They should substantially increase the fraction of prepared cryoEM samples that yield useable data and the quality of the data obtained.

Aspects of the present disclosure have been described in detail with reference to the illustrated embodiments: those skilled in the art will recognize, however, that many modifications may be made thereto without departing from the scope of the present disclosure. The present disclosure is not limited to the precise construction and compositions disclosed herein: any and all modifications, changes, and variations apparent from the foregoing descriptions are within the scope of the disclosure as defined by the appended claims. Moreover, the present concepts expressly include any and all combinations and subcombinations of the preceding elements and features. Additional features may be reflected in the following clauses:

Clause 1: a sample support for cryo-electron microscopy, comprising: a standard 3.05 millimeter diameter, 10-25 micrometer thick circular metal grid; a metal or carbon foil that covers one face of the grid: where the foil has regions with at least two different thicknesses, where at least one foil region has an array of through-holes of diameter between 0.2 and 10 micrometers; and where the boundary between two regions of different thickness forms a step edge, such that the receding contact line of a liquid drop deposited on the foil is pinned by the step edge.

Clause 2: the sample support of clause 1, where the foil regions have a thickness between 5 and 150 nm.

Clause 3: the sample support of clause 1 or clause 2, where the step edge between regions of different thickness has a maximum slope greater than 30 degrees and preferably greater than 60 degrees.

Clause 4: the sample support of any one of clauses 1 to 3, where the step edge forms a circle or an oval.

Clause 5: the sample support of any one of clauses 1 to 4, where the step edge forms a closed shape.

Clause 6: the sample support of any one of clauses 1 to 5, where the smallest lateral dimension of the thinnest foil region is between 20 and 500 micrometers.

Clause 7: the sample support of any one of clauses 1 to 6, where the thicker and thinner regions form an annular ring, where the ring is thicker than adjacent foil regions, and where the outer edge of the ring can pin the advancing contact line of liquid deposited within the ring, and the inner edge can pin the receding contact line of liquid deposited within the ring.

Clause 8: the sample support of clause 7, where the width of the annular ring is between 5 and 100 micrometers.

Clause 9: a system for controlled deposition of nanoliter volumes of biomolecule-containing liquid onto a substantial fraction of the foil area of a sample support used in cryo-electron microscopy, the method comprising: a deposition head covered with an array of flat-topped pillars: means for depositing a volume of liquid on the top of the pillar array: means for removing liquid leaving isolated drops on each pillar; and means for bringing the drop-covered pillar array in contact with the foil of a cryo-electron microscopy sample support so as to transfer liquid from each pillar to the foil.

Clause 10: the system of clause 9, where a diameter of the pillar array is comparable to the central, electron-microscope-imaging-accessible area of the grid, or roughly 2 to 2.5 millimeters.

Clause 11: the system of clause 9 or clause 10, where the pillars have diameters between 2 and 50 micrometers, corresponding to drop volumes on their tops between 0.1 femtoliters and 10 picoliters per pillar.

Clause 12: the system of any one of clauses 9 to 11, where the pillars are capped by a hydrophilic material, including gold.

Clause 13: the system of any one of clauses 9 to 12, where the uncapped pillar surfaces are hydrophobic.

Clause 14: the system of any one of clauses 9 to 13, where the pillars are made of compliant material including PDMS and SU-8.

Clause 15: the system of any one of clauses 9 to 14, where the areal density of pillars and diameter of pillars is determined by the desired final average liquid thickness across the full area of the foil to be contacted by the array, in the range of 5 to 150 nanometers, and to an average liquid volume per unit area between 10 and 150 picoliters per square millimeter.

Clause 16: the system of any one of clauses 9 to 15, where the means for depositing the volume of liquid on the pillar array may include a pipette or a syringe.

Clause 17: the system of any one of clauses 9 to 15, where the means for depositing a volume of liquid on the pillar array may comprise a series of through-channels running from the rear of the deposition head to the spaces between pillars, through which liquid can be injected from the rear of the deposition head, into the spaces between pillars and onto the tops of the pillars.

Clause 18: the system of any one of clauses 9 to 17, where the means for removing liquid from the pillar arrays include vibration of the pillar array and blotting.

Clause 19: the system of any one of clauses 9 to 17, where the means for removing liquid comprises a series of through-channels in the deposition head that connect to the space between pillars to allow liquid in the space between pillars to be withdrawn by section and through the rear of the deposition head.

Clause 20: the system of clause 17 or clause 19, where the deposition head connects to a syringe and syringe pump, which inject liquid into and onto the deposition head and then remove liquid from it.

Clause 21: the system of any one of clauses 9 to 20, where the means for bringing the deposition head into contact with a foil-covered grid is a linear motion stage.

Clause 22: the system of clause 21, where the linear motion stage uses a screw drive or a piezo electric drive to achieve positional steps and accuracy of 10 micrometers or better and preferably 1 micrometer or better.

Clause 23: the system of clause 22, where the linear motion stage includes a sensor that can detect when the deposition head contacts the foil and grid.

Clause 24: the system of any one of clauses 9 to 23, where the pillar array contains pillars of different diameters in different regions that will deposit different amounts of liquid per unit area on a foil and thus produce liquid films of different average thickness on different regions of the foil.

Clause 25: a sample support for a cryo-electron microscopy process, the sample support comprising: a support grid with first and second grid faces; and a foil covering the first face of the grid, the foil including a plurality of foil regions each having a respective distinct thickness, wherein at least one of the foil regions has an array of through-holes, and wherein a boundary between the foil regions having the distinct thicknesses forms a step edge configured to pin thereto a receding contact line of a liquid drop deposited on the foil.

Clause 26: the sample support of clause 25, wherein the support grid is substantially flat and substantially circular.

Clause 27: the sample support of clause 26, wherein the support grid has a diameter of about 2.9 millimeters (mm) to about 3.1 mm and a thickness of about 10 micrometers (μm) to about 25 μm.

Clause 28: the sample support of any one of clauses 25 to 27, wherein the foil includes a metal or carbon foil.

Clause 29: the sample support of any one of clauses 25 to 28, wherein the holes in the array of through-holes are circular and have a diameter of between about 0.2 micrometers (μm) and about 10 μm.

Clause 30: the sample support of any one of clauses 25 to 29, wherein the distinct thicknesses of the foil regions are between about 5 nanometers (nm) and about 150 nm.

Clause 31: the sample support of any one of clauses 25 to 30, wherein the step edge includes an angled surface with a maximum slope greater than about 30 degrees.

Clause 32: the sample support of any one of clauses 25 to 31, wherein the step edge forms a circle or an oval.

Clause 33: the sample support of any one of clauses 25 to 32, wherein the step edge forms a closed shape.

Clause 34: the sample support of any one of clauses 25 to 33, wherein a smallest lateral dimension of a thinnest one of the foil regions is between about 20 micrometers (μm) and about 500 μm.

Clause 35: the sample support of any one of clauses 25 to 34, wherein the foil regions form an annular ring having a ring thickness, wherein multiple ones of the foil regions inside and outside of the annular ring have a foil thickness less than the ring thickness.

Clause 36: the sample support of clause 35, wherein an outer edge of the annular ring is configured to pin an advancing contact line of a liquid deposited within the ring, and an inner edge of the annular ring is configured to pin the receding contact line of liquid deposited within the ring.

Clause 37: the sample support of clause 35, wherein a width of the annular ring is between about 5 micrometers (μm) and about 100 μm.

Clause 38: a system for depositing a liquid onto a sample support used in a cryo-electron microscopy process, the sample support including a support grid and a foil, the system comprising: a deposition head including an array of pads lying within a first plane: a liquid depositing device configured to deposit a predefined volume of liquid on top of the array of pads: a liquid removing device configured to remove a predefined amount of the liquid and thereby leave isolated drops of the liquid on each pad in the array of pads; and a pad moving device configured to move the array of pads with the drops of the liquid into contact with the foil of the sample support to thereby transfer the liquid from each of the pads to the foil.

Clause 39: the system of clause 38, wherein the deposition head is covered with the pads, and wherein the pads are substantially flat.

Clause 40: the system of clause 38 or 39, wherein the liquid removing device, by removing the predefined amount of the liquid, covers each of the pads with the isolated drops of the liquid.

Clause 41: the system of any one of clauses 38 to 40, wherein the diameter of the pad array is approximately equal to an electron-microscope-imaging-accessible area of the grid.

Clause 42: the system of clause 41, wherein the diameter of the pad array is about 2 millimeters (mm) to about 2.5 mm.

Clause 43: the system of any one of clauses 38 to 42, wherein each of the pads has a diameter of between about 2 micrometers (μm) and about 50 μm and is configured to support thereon a drop volume of the drops of the liquid of between about 0.1 femtoliters and about 10 picoliters per pillar.

Clause 44: the system of any one of clauses 38 to 43, wherein top surfaces of the pads are hydrophilic or are covered with a hydrophilic material.

Clause 45: the system of any one of clauses 38 to 44, wherein a surface of the deposition head between the pads is hydrophobic or is covered with a hydrophobic material.

Clause 46: the system of any one of clauses 38 to 45, wherein the pads are made with a compliant material, the compliant material including a polydimethylsiloxane (PDMS) and/or an SU-8 epoxy-based photoresist.

Clause 47: the system of any one of clauses 38 to 46, wherein an areal density of the pads and a diameter of the pads corresponds to a predefined final average liquid thickness across a full area of the foil to be contacted by the array of pads and to a predefined average liquid volume per unit area.

Clause 48: the system of clause 47, wherein the predefined final average liquid thickness is between about 5 nanometers (nm) and about 150 nm and the average liquid volume per unit area is between about 10 picoliters (pL) and about 150 pL per square millimeter

Clause 49: the system of any one of clauses 38 to 49, wherein the liquid depositing device includes a pipette or a syringe.

Clause 50: the system of any one of clauses 38 to 49, wherein the liquid depositing device includes a series of through-channels, extending from a rear of the deposition head to spaces between the pads, through which liquid is injectable from the rear of the deposition head into the spaces between the pads and onto the tops of the pads.

Clause 51: the system of any one of clauses 38 to 50, wherein the liquid removing device includes a vibration device operable to vibrate the array of pad and a blotting device operable to extract liquid.

Clause 52: the system of any one of clauses 38 to 51, wherein the liquid removing device includes a series of through-channels in the deposition head that connect to spaces between the pads, wherein the series of through-channels is configured to withdraw liquid in spaces between the pads through the rear of the deposition head.

Clause 53: the system of any one of clauses 38 to 52, wherein the deposition head connects to a syringe and a syringe pump collectively configured to inject liquid into and/or onto the deposition head and remove liquid from the deposition head.

Clause 54: the system of any one of clauses 38 to 53, wherein the pad moving device includes a linear motion stage.

Clause 55: the system of clause 54, wherein the linear motion stage includes a screw drive or a piezoelectric drive configured to move the array of pads in positional steps with an accuracy of 10 micrometers or better.

Clause 56: the system of clause 55, wherein the linear motion stage includes a sensor operable to detect contact of the deposition head with the foil and the grid.

Clause 57: the system of any one of clauses 38 to 56, wherein the pad array contains pads of different diameters in different regions to deposit different amounts of liquid per unit area on the foil to thereby produce liquid films of different average thickness on different regions of the foil.

1-13. (canceled)

14. A system for depositing a sample-containing liquid onto a sample support used in a cryo-electron microscopy process, the sample support including a support grid and a foil, the system comprising:
a deposition head including an array of pads lying within a first plane;
a liquid depositing device configured to deposit a volume of the sample-containing liquid on top of the array of pads;
a liquid removing device configured to remove an amount of the sample-containing liquid and thereby leave isolated drops of the sample-containing liquid on each pad in the array of pads; and
a deposition head moving device configured to move the array of pads with the drops of the sample-containing liquid into contact with the foil of the sample support to thereby transfer the sample-containing liquid from each of the pads to the foil.

15. The system of claim 14, wherein the deposition head is covered with the pads, and wherein the pads are substantially flat.

16. (canceled)

17. The system of claim 14, wherein the array of pads is arranged within a circle on the deposition head, and wherein a diameter of the array of pads is approximately equal to an electron-microscope-imaging-accessible area of the support grid of the sample support.

18. The system of claim 17, wherein the diameter of the array of pads is about 2 millimeters (mm) to about 2.5 mm.

19. The system of claim 14, wherein each of the pads has a diameter of between about 2 micrometers (μm) and about 50 μm and is configured to support thereon a drop volume of the drops of the sample-containing liquid of between about 0.1 femtoliters and about 10 picoliters.

20. The system of claim 14, wherein top surfaces of the pads are hydrophilic or are covered with a hydrophilic material.

21. The system of claim 14, wherein a surface of the deposition head between the pads is hydrophobic or is covered with a hydrophobic material.

22. The system of claim 14, wherein the pads are made with a compliant material, the compliant material including a polydimethylsiloxane (PDMS) and/or an SU-8 epoxy-based photoresist.

23. The system of claim 14, wherein an areal density of the pads, a diameter of the pads, and a liquid contact angle on the pads corresponds to a predefined final average liquid thickness across a full area of the foil to be contacted by the array of pads and to a predefined average liquid volume per unit area.

24. The system of claim 23, wherein the predefined final average liquid thickness is between about 5 nanometers (nm) and about 150 nm and the average liquid volume per unit area is between about 10 picoliters (pL) and about 150 pL per square millimeter.

25. The system of claim 14, wherein the liquid depositing device includes a pipette or a syringe.

26. (canceled)

27. The system of claim 14, wherein the liquid removing device includes a vibration device operable to vibrate the array of pads and/or a blotting device operable to extract liquid from the array of pads.

28. The system of claim 14, wherein the liquid removing device includes a series of through-channels in the deposition head that connects to spaces between the pads, wherein the series of through-channels is configured to withdraw the sample-containing liquid in the spaces between the pads through the rear of the deposition head.

29. The system of claim 14, wherein the deposition head connects to a syringe and a syringe pump collectively configured to inject the sample-containing liquid into and/or onto the deposition head and remove the sample-containing liquid from the deposition head.

30. The system of claim 14, wherein the deposition head moving device includes a linear motion stage configured to move the deposition head and the array of pads.

31. The system of claim 30, wherein the linear motion stage includes a screw drive or a piezoelectric drive configured to move the deposition head and the array of pads in positional steps with an accuracy of about 10 micrometers or better.

32. The system of claim 31, wherein the linear motion stage includes a sensor operable to detect contact of the deposition head with the foil and the grid.

33. The system of claim 14, wherein the array of pads contains pads of different diameters in different regions to deposit different amounts of the sample-containing liquid per unit area on the foil to thereby produce liquid films of different average thickness on different regions of the foil.

34. The system of claim 14, wherein a contact angle of the sample-containing liquid on each of the pads is between about 0° and 30°.

35. The system of claim 14, wherein the deposition head includes a series of through-channels extending from a rear of the deposition head to spaces between the pads, the series of through-channels configured to receive therethrough the sample-containing liquid to be deposited on the pads by injecting the sample-containing liquid from the rear of the deposition head into the spaces between the pads and onto tops of the pads.
